(19) United States
(12) Patent Application Publication
(10) Pub. No.: US 2014/0035499 A1
(43) Pub. Date: Feb. 6, 2014

(54) DRIVING APPARATUS HAVING CURRENT DETECTION FUNCTION AND MOTOR DRIVING APPARATUS HAVING CURRENT DETECTION FUNCTION

(71) Applicant: SAMSUNG ELECTRO-MECHANICS CO., LTD., Gyunggi-do (KR)

(72) Inventor: Joo Yul KO, Gyunggi-do (KR)

(73) Assignee: SAMSUNG ELECTRO-MECHANICS CO., LTD., Gyunggi-do (KR)

(21) Appl. No.: 13/660,610

(22) Filed: Oct. 25, 2012

(30) Foreign Application Priority Data
Jul. 31, 2012 (KR) 10-2012-0084158

(51) Int. Cl. H03K 17/687; H02P 6/14

(52) U.S. Cl. 318/400.29; 327/404

(57) ABSTRACT

There are provided a driving apparatus having a current detection function and a motor driving apparatus having a current detection function that are capable of detecting current without a voltage drop by using a dummy transistor connected to a driving transistor in parallel. The driving apparatus includes: a driving unit including at least one transistor connected between a driving power terminal supplying driving power and a ground and switched according to a switching control signal to drive a preset device; and a detecting unit including at least one dummy transistor connected to the at least one transistor in parallel and switched together with the at least one transistor according to the switching control signal to detect current flowing in the at least one dummy transistor.

### CROSS-REFERENCE TO RELATED APPLICATIONS

This application claims the priority of Korean Patent Application No. 10-2012-0084158 filed on Jul. 31, 2012, in the Korean Intellectual Property Office, the disclosure of which is incorporated herein by reference.

### BACKGROUND OF THE INVENTION

1. Field of the Invention

The present invention relates to a driving apparatus having a current detection function for an electronic product, and more particularly, to a motor driving apparatus having a current detection function for driving a motor.

2. Description of the Related Art

Recently, due to demand for personal, home, and office electrical appliances, electronic devices and the like, the use of electrical devices and electronic devices has rapidly increased.

Interiors of these devices may be provided with a driving circuit in order to drive a specific operation. An example of such a device may include a motor.

A brushless direct current (BLDC) motor generally means a DC motor able to conduct a current or adjust a current direction using a non-contact position detector and a semiconductor element rather than using a mechanical contact unit such as a brush, a commutator, or the like, in a DC motor.

In order to drive the BLDC motor, a driving apparatus may be used.

FIG. 1 is a configuration diagram of a general motor driving apparatus.

Referring to FIG. 1, a general motor driving apparatus 10 may include a controlling unit 11 and a driving unit 12.

The controlling unit 11 may control driving of the motor, and the driving unit 12 may drive the motor by turning four field effect transistors (FETs) on or off according to a driving signal of the controlling unit 11.

FIG. 2 is a diagram showing driving signals of the motor driving apparatus.

Referring to FIG. 2, the driving signals transferred from the controlling unit 11 to the driving unit 12 may be divided into four types thereof and may be transferred in a sequence of identification numerals \textcircled{1}, \textcircled{2}, \textcircled{3}, and \textcircled{4}.

That is, a first PMOS FET P1 and a second NMOS FET N2 may be turned on by a driving signal represented by identification numeral \textcircled{1}, and the first PMOS FET P1 and the second NMOS FET N2 may be turned off while a second PMOS FET P2 and a first NMOS FET N1 maybe turned on by a driving signal represented by identification numeral \textcircled{2}.

Again, the second PMOS FET P2 and the first NMOS FET N1 may be turned off and the first PMOS FET P1 and the second NMOS FET N2 may be turned on by a driving signal represented by identification numeral \textcircled{3}, and the first PMOS FET P1 and the second NMOS FET N2 may be turned off and the second PMOS FET P2 and the first NMOS FET N1 may be turned on by a driving signal represented by identification numeral \textcircled{4}.

In this driving scheme, when the first PMOS FET P1 and the second PMOS FET P2 are turned on, pulse width modulation (PWM) signals (oblique line portions of FIG. 2) are generated, whereby a speed of the motor may be adjusted.

The motor driving apparatus as described above may perform a control operation of detecting current flowing in the motor through a resistor connected to a ground and providing a PWM signal based on the detected signal to appropriately adjust a speed of the motor to a set level or stop the driving of the motor at the time of overcurrent in order to accurately drive the motor.

However, the detection scheme as described above has a problem in that power efficiency may be reduced due to a voltage drop by the resistor.

### RELATED ART DOCUMENT

(Patent Document 1) Korean Patent Laid-open Publication No. 10-2006-0045357

### SUMMARY OF THE INVENTION

An aspect of the present invention provides a driving apparatus having a current detection function and a motor driving apparatus having a current detection function that are capable of detecting current without a voltage drop by using a dummy transistor connected in parallel with a driving transistor.

According to an aspect of the present invention, there is provided a driving apparatus having a current detection function, the driving apparatus including: a driving unit including at least one transistor connected between a driving power terminal supplying driving power and a ground and switched according to a switching control signal to drive a preset device; and a detecting unit including at least one dummy transistor connected to the at least one transistor in parallel and switched together with the at least one transistor according to the switching control signal to detect current flowing in the at least one dummy transistor.

The at least one dummy transistor may have at least one dummy transistor has a resistance element greater than a resistance element of the at least one transistor.

The detecting unit may detect the current flowing in the at least one dummy transistor according to a ratio of the resistance element of the at least one dummy transistor to the resistance element of the at least one transistor.

The detecting unit may further include a detection resistor connected between the at least one dummy transistor and the ground to detect the current flowing in the at least one dummy transistor.

The at least one dummy transistor and the at least one transistor may have the same electrical polarity.

According to another aspect of the present invention, there is provided a motor driving apparatus having a current detection function, the motor driving apparatus including: a driving unit including a plurality of pairs of transistors connected between a driving power terminal supplying driving power and a ground, connected to each other in parallel, and switched according to a switching control signal to drive a motor; and a detecting unit including at least one dummy transistor connected in parallel with at least one transistor of the plurality of pairs of transistors and switched together with the at least one transistor according to the switching control signal to detect current flowing in the at least one dummy transistor.

In the driving unit, the plurality of pairs of transistors may include: a first pair of transistors including a first p-type metal oxide semiconductor field-effect transistor (PMOS FET) electrically connected between the driving power terminal supplying driving power and the ground and a first n-type MOS FET (NMOS FET) electrically connected between the first PMOS FET and the ground; and a second pair of transistors including a second PMOS FET connected to the driving power terminal in parallel with the first PMOS FET and electrically connected between the driving power terminal and the ground and a second NMOS FET electrically connected between the second PMOS FET and the ground.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a configuration diagram of a general motor driving apparatus;

FIG. 2 is a diagram showing driving signals of the motor driving apparatus;

FIG. 3 is a schematic circuit diagram of a driving apparatus according to an embodiment of the present invention;

FIG. 4 is a schematic configuration diagram of a motor driving apparatus according to the embodiment of the present invention; and

FIG. 5 is a diagram showing current flow in the motor driving apparatus according to the embodiment of the present invention.

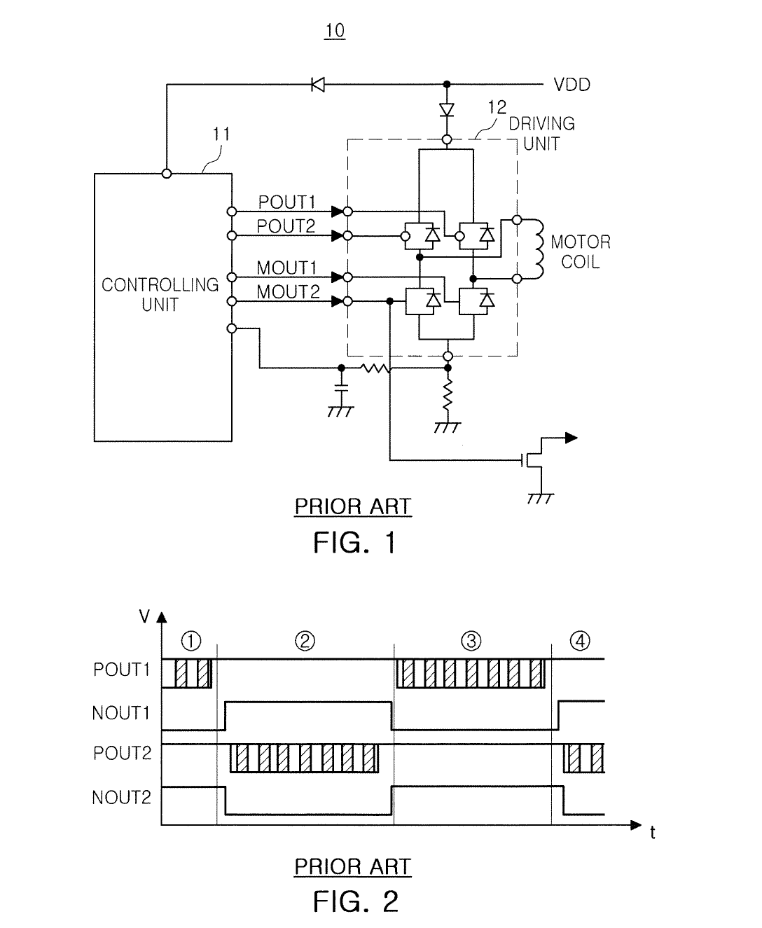

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

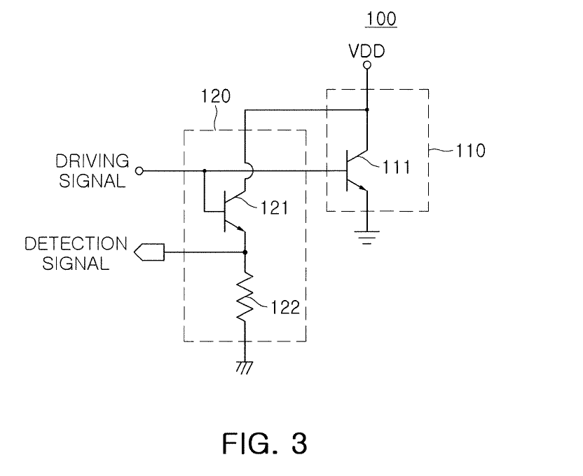

FIG. 3 is a schematic circuit diagram of a driving apparatus according to an embodiment of the present invention.

Referring to FIG. 3, the driving apparatus according to the embodiment of the present invention may include a driving unit 110 and a detecting unit 120.

The driving unit 110 may include at least one transistor 111 connected between a driving power terminal supplying driving power VDD and a ground.

The at least one transistor 111 may be switched on or off by receiving a driving signal applied from the outside to a gate thereof, thereby driving a target device to be driven.

The detecting unit 120 may include at least one dummy transistor 121 and a detection resistor 122.

The dummy transistor 121 may receive the driving signal in a gate thereof in a similar manner to the transistor 111 of the driving unit 110. Therefore, when the transistor 111 of the driving unit 110 is switched on, the dummy transistor 121 may also be switched on, while when the transistor 111 of the driving unit 110 is switched off, the dummy transistor 121 may also be switched off.

To this end, the dummy transistor 121 and the transistor 111 of the driving unit 110 may have the same electrical polarity.

The detection resistor 122 may be connected between the dummy transistor 121 and the ground to detect current flowing in the dummy transistor 121.

Here, the dummy transistor 121 may form circuit area and resistance ratios with the transistor 111 of the driving unit 110 and have a circuit area and resistance larger than those of the transistor 111 of the driving unit 110.

Therefore, the current flowing in the dummy transistor 121 may have a current value depending on the circuit area and resistance ratios with respect to current flowing in the transistor 111 of the driving unit 110.

For example, the circuit area and resistance ratios of the dummy transistor 121 to the transistor 111 of the driving unit 110 may be set to be 1000:1. Therefore, a ratio of the current flowing in the dummy transistor 121 to the current flowing in the transistor 111 of the driving unit 110 may be 1:1000.

That is, almost all of the current flowing due to the driving power supply VDD may flow in the transistor 111 of the driving unit 110 and only a small amount of current in which a resistance drop is barely generated may flow in the dummy transistor 121.

A detection signal detected by the detection resistor 122 may be transferred to an external control circuit. Since the external control circuit may already recognize the circuit area and resistance ratios of the dummy transistor 121 and the transistor 111 of the driving unit 110, the external control circuit may scale current information included in the detection signal to obtain accurate current information.

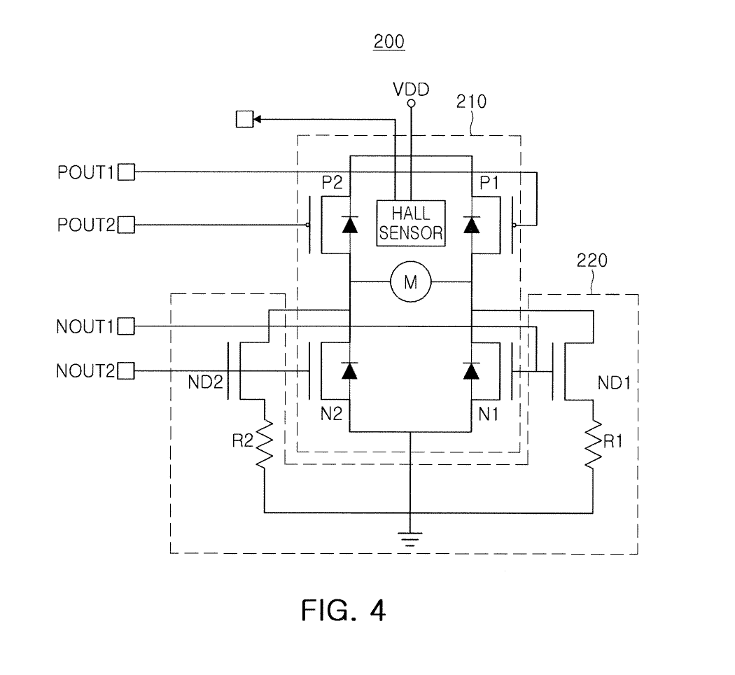

FIG. 4 is a schematic configuration diagram of a motor driving apparatus according to the embodiment of the present invention.

The motor driving apparatus according to the embodiment of the present invention may include a driving unit 210 and a detecting unit 220. The driving unit 210 may include a transistor switched on or off according to the driving signal, and a motor may be driven according to switching on or off operation of the transistor.

More specifically, the driving unit 210 may have two pairs of transistors, and each of the two pairs of transistors may include two transistors. As a result, the driving unit 210 may include a total of four transistors. The fourth transistors may be configured of two p-type metal oxide semiconductor field effect transistors (PMOS FETs) P1 and P2 and two n-type MOS FETs (NMOS FETs) N1 and N2.

The PMOS FETs P1 and P2 may include a first PMOS FET denoted by reference numeral P1 and a second PMOS FET denoted by reference numeral P2, and the NMOS FETs N1 and N2 may include a first NMOS FET denoted by reference numeral N1 and a second NMOS FET denoted by reference numeral N2. The first PMOS FET P1 may be electrically connected between the driving power terminal for supplying the driving power VDD and the ground, and the first NMOS FET N1 may be electrically connected between the first PMOS FET P1 and the ground.

The second PMOS FET P2 may be connected to the driving power terminal in parallel with the first PMOS FET P1 and be electrically connected between the driving power terminal and the ground, and the second NMOS FET N2 may be electrically connected between the second PMOS FET P2 and the ground.

In addition, the motor is connected to a connection point between the first PMOS FET P1 and the first NMOS FET N1 and a connection point between the second PMOS FET P2 and the second NMOS FET N2, such that the motor may be driven by switching operations of the first PMOS FET P1 and the second NMOS FET N2 and switching operations of the second PMOS FET P2 and the first NMOS FET N1.

Briefly describing a motor driving operation, the first PMOS FET P1 and the second NMOS FET N2, and the second PMOS FET P2 and the first NMOS FET N1 may be alternately turned on or off by driving signals POUT1, POUT2, NOUT1, and NOUT2 from the outside.

That is, the first PMOS FET P1 and the second NMOS FET

N2 may be turned off and the second PMOS FET P2 and the first NMOS FET N1 may be turned on by the driving signals POUT1, POUT2, NOUT1, and NOUT2 from the outside, and the second PMOS FET P2 and the first NMOS FET N1 may be turned off and the first PMOS FET P1 and the second NMOS FET N2 may be turned on by the driving signals POUT1, POUT2, NOUT1, and NOUT2.

The detecting unit 220 may include dummy transistors ND1 and ND2 and detection resistors R1 and R2. The dummy transistors ND1 and ND2 may include a first dummy transistor denoted by reference numeral ND1 and a second dummy transistor denoted by reference numeral ND2.

The dummy transistors ND1 and ND2 may be connected to at least one MOS FET of the driving unit in parallel.

More specifically, the dummy transistors ND1 and ND2 may be connected to the first NMOS FET N1 and the second NMOS FET N2 in parallel, respectively.

The driving signals NOUT1 and NOUT2 input to gates of the first NMOS FET N1 and the second NMOS FET N2 may be input to gates of the dummy transistors ND1 and ND2.

That is, the first dummy transistor ND1 may be connected to the first NMOS FET N1 in parallel to receive the driving signal NOUT1 together with the first NMOS FET N1, and the second dummy transistor ND2 may be connected to the second NMOS FET N2 in parallel to receive the second driving signal NOUT2 together with the second NMOS FET N2.

Although not shown, the first and second dummy transistors ND1 and ND2 may also be connected to the first and second PMOS FETs in parallel, respectively, to receive the driving signals POUT1 and POUT2 together with the first and second PMOS FETs.

The detection resistors R1 and R2 may be connected between the respective first and second dummy transistor ND1 and ND2 and the ground.

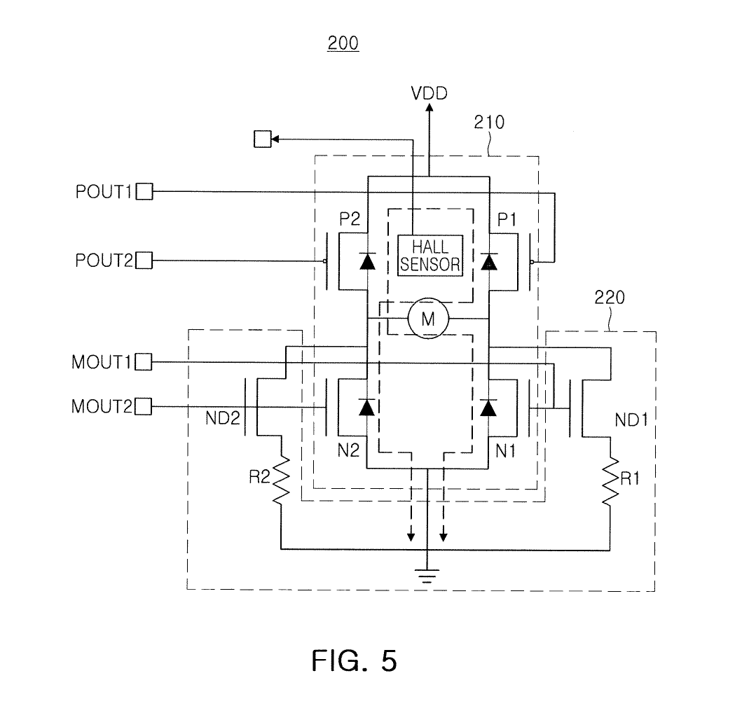

FIG. 5 is a diagram showing current flow in the motor driving apparatus according to the embodiment of the present invention.

Referring to FIGS. 4 and 5, as described above, the first PMOS FET P1 and the second NMOS FET N2 may be turned off and the second PMOS FET P2 and the first NMOS FET N1 may be turned on by the driving signals POUT1, POUT2, NOUT1, and NOUT2, and the second PMOS FET P2 and the first NMOS FET N1 may be turned off and the first PMOS FET P1 and the second NMOS FET N2 may be turned on by the driving signals POUT1, POUT2, NOUT1, and NOUT2. Therefore, current flow as depicted by arrows in FIGS. 4 and 5 may be generated.

In this case, the dummy transistors ND1 and ND2 may form circuit area and resistance ratios with the first and second NMOS FETs N1 and N2, and have a circuit area and resistance that are larger than those of the first and second NMOS FETs N1 and N2.

Therefore, current flowing in the dummy transistors ND1 and ND2 may have a current value depending on the above-mentioned circuit area and resistance ratios with respect to the current flowing in the first and second NMOS FETs N1 and N2.

For example, the circuit area and resistance ratios of the dummy transistors ND1 and ND2 to the first and second NMOS FETs N1 and N2 may be set to 1000:1. Therefore, a ratio of the current flowing in the dummy transistors ND1 and ND2 to the current flowing in the first and second NMOS FETs N1 and N2 may be 1:1000.

That is, almost all of the current flowing due to the driving power supply VDD may flow in the first and second NMOS FETs N1 and N2 and only a small amount of current in which a resistance drop is barely generated may flow in the dummy transistors ND1 and ND2.

As in the Related Art Document, in the case in which a detection resistor is connected between an NMOS FET used for driving of the motor and a ground, a voltage of driving power may be represented by the following Equation 1.

$$VDD = ( {Ron}_{PMOS} + {Ron}_{NMOS} + {R}_{sensing} + {R}_{inductor} ) \times I + {L}_{inductor} \frac{d I}{d t} + BEMF \qquad ( Equation 1 )$$

However, in the motor driving apparatus according to the embodiment of the present invention, the detection resistor is connected between the dummy transistor and the ground to detect the current, a voltage of the driving power may be represented by the following Equation 2.

$$VDD = ( {Ron}_{PMOS} + {Ron}_{NMOS} + {R}_{inductor} ) \times I + {L}_{inductor} \frac{d I}{d t} + BEMF \qquad ( Equation 2 )$$

Comparing Equations 1 and 2, it may be appreciated that a voltage drop due to the detection resistor Rsensing is removed.

A detection signal detected by the detection resistors R1 and R2 may be transferred to an external control circuit. Since the external control circuit already recognizes the circuit area and resistance ratios of the dummy transistors ND1 and ND2 to the first and second NMOS FETs N1 and N2, the external control circuit may scale current information included in the detection signal to obtain accurate current information.

As set forth above, according to the embodiment of the present invention, a dummy transistor connected to a driving transistor in parallel is used to detect current without a voltage drop, whereby a reduction in power efficiency due to power detection can be prevented.

While the present invention has been shown and described in connection with the embodiments, it will be apparent to those skilled in the art that modifications and variations can be made without departing from the spirit and scope of the invention as defined by the appended claims.

What is claimed is:

1. A driving apparatus having a current detection function, the driving apparatus comprising:
a driving unit including at least one transistor connected between a driving power terminal supplying driving power and a ground and switched according to a switching control signal to drive a preset device; and
a detecting unit including at least one dummy transistor connected to the at least one transistor in parallel and switched together with the at least one transistor according to the switching control signal to detect current flowing in the at least one dummy transistor.

2. The driving apparatus of claim 1, wherein the at least one dummy transistor has a resistance element gerater than a resistance element of the at least one transistor.

3. The driving apparatus of claim 2, wherein the detecting unit detects the current flowing in the at least one dummy transistor according to a ratio of the resistance element of the at least one dummy transistor to the resistance element of the at least one transistor.

4. The driving apparatus of claim 3, wherein the detecting unit further includes a detection resistor connected between the at least one dummy transistor and the ground to detect the current flowing in the at least one dummy transistor.

5. The driving apparatus of claim 1, wherein the at least one dummy transistor and the at least one transistor have the same electrical polarity.

6. A motor driving apparatus having a current detection function, the motor driving apparatus comprising:
a driving unit including a plurality of pairs of transistors connected between a driving power terminal supplying driving power and a ground, connected to each other in parallel, and switched according to a switching control signal to drive a motor; and
a detecting unit including at least one dummy transistor connected in parallel with at least one transistor of the plurality of pairs of transistors and switched together with the at least one transistor according to the switching control signal to detect current flowing in the at least one dummy transistor.

7. The motor driving apparatus of claim 6, wherein in the driving unit, the plurality of pairs of transistors include:
a first pair of transistors including a first p-type metal oxide semiconductor field-effect transistor (PMOS FET) electrically connected between the driving power terminal supplying driving power and the ground and a first n-type MOS FET (NMOS FET) electrically connected between the first PMOS FET and the ground; and
a second pair of transistors including a second PMOS FET connected to the driving power terminal in parallel with the first PMOS FET and electrically connected between the driving power terminal and the ground and a second NMOS FET electrically connected between the second PMOS FET and the ground.

8. The motor driving apparatus of claim 6, wherein the at least one dummy transistor has a resistance element greater than a resistance element of the at least one transistor.

9. The motor driving apparatus of claim 8, wherein the detecting unit detects the current flowing in the at least one dummy transistor according to a ratio of the resistance element of the at least one dummy transistor to the resistance element of the at least one transistor.

10. The motor driving apparatus of claim 9, wherein the detecting unit further includes a detection resistor connected between the at least one dummy transistor and the ground to detect the current flowing in the at least one dummy transistor.

11. The motor driving apparatus of claim 6, wherein the at least one dummy transistor and the at least one transistor have the same electrical polarity.
